(19) United States
(12) Patent Application Publication
(10) Pub. No.: US 2025/0289657 A1
(43) Pub. Date: Sep. 18, 2025

(54) ARTICLE TRANSFER APPARATUS

(71) Applicant: SAMSUNG ELECTRONICS CO., LTD., Suwon-si (KR)

(72) Inventors: Youngwook KIM, Suwon-si (KR); Sangmin Kim, Suwon-si (KR); Hyoengrak Kim, Suwon-si (KR); Soyoung Baek, Suwon-si (KR); Jaesung Byun, Suwon-si (KR); Donghun Seo, Suwon-si (KR); Yongjun Ahn, Suwon-si (KR); Hyunwoo Lee, Suwon-si (KR); Jeonghun Lim, Suwon-si (KR)

(73) Assignee: SAMSUNG ELECTRONICS CO., LTD., Suwon-si (KR)

(21) Appl. No.: 19/027,263

(22) Filed: Jan. 17, 2025

(30) Foreign Application Priority Data
Mar. 13, 2024 (KR) 10-2024-0035429

(51) Int. Cl. B65G 1/04

(52) U.S. Cl. CPC B65G 1/0464

(57) ABSTRACT

An article transfer apparatus includes a traveling rail including: first rails extending in a first direction and spaced apart from each other in a second direction perpendicular to the first direction; and second rails extending in the second direction and spaced apart from each other in the first direction. The article transfer apparatus further includes a transfer robot on the traveling rail, configured to move in the first direction along two neighboring first rails among the first rails, and move in the second direction along two neighboring second rails among the second rails, the transfer robot including traveling wheels, guide wheels, and a wheel elevator, wherein the guide wheels are in contact with at least one from among a first guide part of the first rails and a second guide part of the second rails while the transfer robot moves on the traveling rail.

### CROSS-REFERENCE TO RELATED APPLICATION

This application is based on and claims priority under 35 U.S.C. § 119 to Korean Patent Application No. 10-2024-0035429, filed on Mar. 13, 2024, in the Korean Intellectual Property Office, the disclosure of which is incorporated by reference herein in its entirety.

### BACKGROUND

### 1. Field

Embodiments of the present disclosure relate to an article transfer apparatus, and more particularly, to an article transfer apparatus including a transfer robot.

### 2. Brief Description of Related Art

Generally, transport of goods in a semiconductor manufacturing plant is performed by an overhead hoist transport (OHT) apparatus. The OHT apparatus includes an overhead rail fixed to the ceiling of a semiconductor manufacturing plant and a transfer robot that moves along a path provided by the overhead rail. While the transfer robot moves along the overhead rail, it is difficult to control the vibration generated in the transfer robot.

### SUMMARY

Embodiments of the present disclosure provide an article transfer apparatus with low friction between a transfer robot and a traveling rail during an elevating operation of the transfer robot.

Embodiments of the present disclosure provide an article transfer apparatus with minimal vibration generated by a transfer robot while traveling along a traveling rail.

In addition, problems solved by embodiments of the present disclosure are not limited to the problems described above, and other problems that are solved may be clearly understood by those of ordinary skill in the art from the following description.

According to embodiments of the present disclosure, a article transfer apparatus is provided and includes: a traveling rail including: first rails extending in a first direction and spaced apart from each other in a second direction perpendicular to the first direction; and second rails extending in the second direction and spaced apart from each other in the first direction; and a transfer robot on the traveling rail, configured to move in the first direction along two neighboring first rails among the first rails, and move in the second direction along two neighboring second rails among the second rails, the transfer robot including traveling wheels, guide wheels, and a wheel elevator, wherein each of the first rails includes a first traveling part and a first guide part protruding in a vertical direction from the first traveling part, wherein each of the second rails includes a second traveling part and a second guide part protruding in the vertical direction from the second traveling part, wherein the wheel elevator is configured to move the traveling wheels in the vertical direction so that some of the traveling wheels are in contact with or spaced apart from the traveling rail, wherein each of guide wheels has a rotating axis in the vertical direction, and wherein the guide wheels are configured such that some of the guide wheels are in contact with at least one from among the first guide part and the second guide part while the transfer robot moves on the traveling rail.

According to embodiments of the present disclosure, a article transfer apparatus is provided and includes: a traveling rail including: first rails extending in a first direction and spaced apart from each other in a second direction perpendicular to the first direction; and second rails extending in the second direction and spaced apart from each other in the first direction; and a transfer robot on the traveling rail, configured to move in the first direction along two neighboring first rails among the first rails, and move in the second direction along two neighboring second rails among the second rails, the transfer robot including traveling wheels, guide wheels, and a wheel elevator, wherein each of the first rails includes a first traveling part and a first guide part protruding in a vertical direction from the first traveling part, wherein each of second rails includes a second traveling part and a second guide part protruding in the vertical direction from the second traveling part, wherein a horizontal width of the first guide part and the second guide part narrows in the vertical direction, wherein each of the guide wheels has a rotating axis in the vertical direction, and wherein the guide wheels are configured such that some of the guide wheels are in contact with at least one from among the first guide part and the second guide part while the transfer robot moves on the traveling rail.

According to embodiments of the present disclosure, a article transfer apparatus is provided and includes: a traveling rail including: first rails extending in a first direction and spaced apart from each other in a second direction perpendicular to the first direction; and second rails extending in the second direction and spaced apart from each other in the first direction; and a transfer robot on the traveling rail, configured to move in the first direction along two neighboring first rails among the first rails, and move in the second direction along two neighboring second rails among the second rails, the transfer robot including traveling wheels, guide wheels, and a wheel elevator, wherein each of the first rails includes a first traveling part and a first guide part protruding in a vertical direction from the first traveling part, wherein each of the second rails includes a second traveling part and a second guide part protruding in the vertical direction from the second traveling part, wherein a horizontal width of the first guide part and the second guide part decreases in the vertical direction, wherein each of the guide wheels has a rotating axis in the vertical direction, wherein the guide wheels are configured such that some of the guide wheels are in contact with at least one from among the first guide part and the second guide part while the transfer robot moves on the traveling rail, and wherein a horizontal width of each of the guide wheels decreases towards a bottom surface of the guide wheels.

### BRIEF DESCRIPTION OF DRAWINGS

Embodiments of the present disclosure will be more clearly understood from the following detailed description taken in conjunction with the accompanying drawings in which:

FIG. 1 is a perspective view schematically showing an article transfer apparatus according to an embodiment;

FIG. 2 is a cross-sectional view schematically illustrating a cutaway of the article transfer apparatus of FIG. 1;

FIG. 3 is a perspective view schematically showing a part of a traveling rail of an article transfer apparatus according to an embodiment;

FIG. 4 is a plan view schematically illustrating the traveling rail of FIG. 3;

FIG. 5 is a perspective view schematically showing a part of a transfer robot of an article transfer apparatus according to an embodiment;

FIG. 6 is a plan view schematically showing a part of an article transfer apparatus according to an embodiment;

FIGS. 7A to 7C are cross-sectional views schematically showing the article transfer apparatus of FIG. 6, which is taken along a line A-A′ of FIG. 6;

FIG. 8 is a cross-sectional view schematically illustrating a cutaway of an article transfer apparatus according to an embodiment;

FIG. 9 is a cross-sectional view schematically illustrating a cutaway of an article transfer apparatus according to an embodiment; and

FIG. 10 is a cross-sectional view schematically illustrating a cutaway of an article transfer apparatus according to an embodiment.

### DETAILED DESCRIPTION

Since embodiments of the present disclosure may undergo various changes and have various forms, some non-limiting example embodiments of the present disclosure will be illustrated in the drawings and described in detail. However, this is not intended to limit the embodiments of the present disclosure to a specific form.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

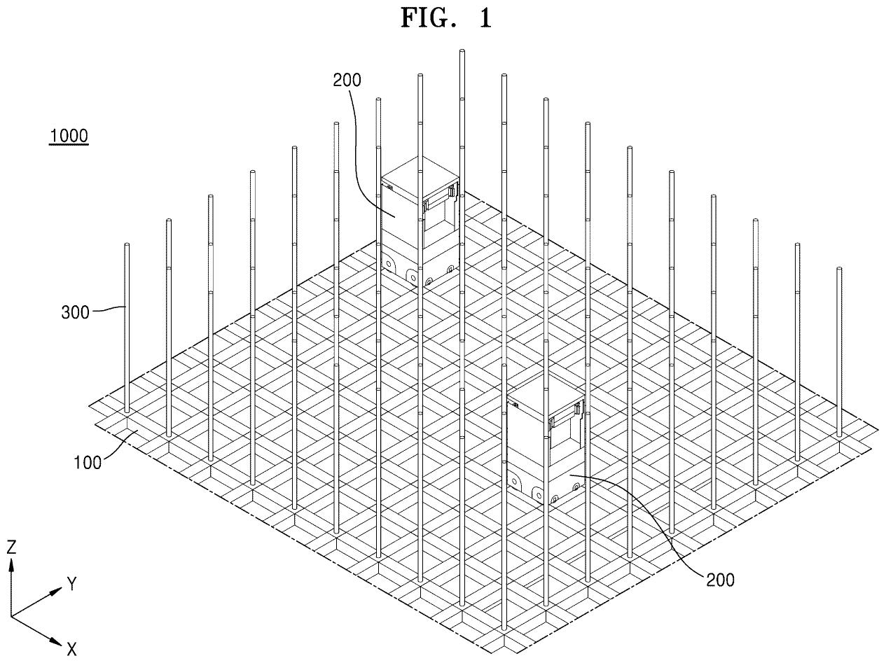

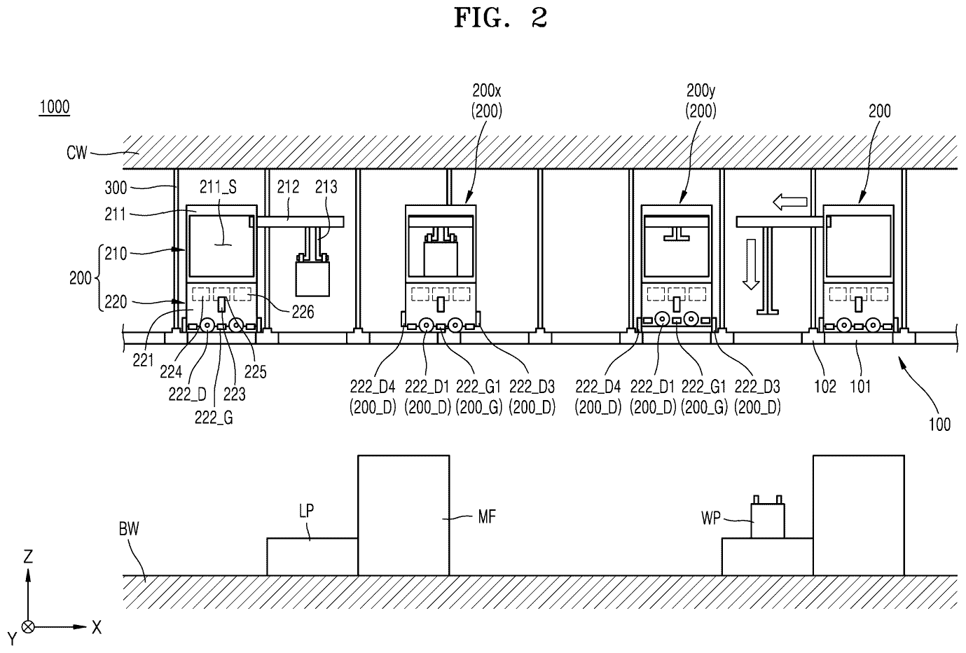

FIG. 1 is a perspective view schematically showing an article transfer apparatus according to an embodiment. FIG. 2 is a cross-sectional view schematically illustrating a cutaway of the article transfer apparatus of FIG. 1.

In this specification, a direction parallel to a ceiling wall CW is defined as a first direction (X direction), a direction perpendicular to the ceiling wall CW is defined as a vertical direction (Z direction), and a direction perpendicular to the first direction (X direction) and the vertical direction (Z direction) is defined as a second direction (Y direction). The first direction (X direction) and the second direction (Y direction) may be examples of a horizontal direction. A horizontal width may refer to a length in the horizontal direction (X direction and/or Y direction), and a vertical length may refer to a length in the vertical direction (Z direction). A horizontal transfer may refer to a transfer in the horizontal direction (X direction and/or Y direction), and a vertical transfer may refer to a transfer in the vertical direction (Z direction).

Referring to FIGS. 1 and 2, an article transfer apparatus 1000 may include a traveling rail 100 and a transfer robot 200.

The article transfer apparatus 1000 may be configured to transfer an article WP. In embodiments, the article transfer apparatus 1000 is provided to a semiconductor device manufacturing plant, and may be configured to transfer the article WP or temporarily store the article WP in the semiconductor device manufacturing plant.

In some embodiments, the article WP may be a container in which a substrate for manufacturing a semiconductor device is accommodated. For example, the article WP may include any one from among a closed container such as a front open unified pod (FOUP) configured to store multiple substrates, a magazine configured to store multiple substrates, and a tray configured to store multiple substrates.

The article transfer apparatus 1000 may be configured to transfer the article WP between facilities MF installed on a bottom BW of the semiconductor device manufacturing plant. The article transfer apparatus 1000 is fixed on the ceiling wall CW of the semiconductor device manufacturing plant, and a transfer of the article WP by the article transfer apparatus 1000 may be performed on the facilities MF.

In some embodiments, the facilities MF may include manufacturing facilities configured to perform a semiconductor process on a substrate. For example, manufacturing facilities may include facilities configured to perform a diffusion process, a photolithography process, an etching process, a deposition process, a metallization process, an ion implantation process, a cleaning process, a polishing process, and/or a packaging process on a substrate. Each of the facilities MF may include a load port LP on which the article WP is mounted.

The traveling rail 100 may be configured to guide traveling of the transfer robot 200 in the first direction (X direction) and the second direction (Y direction). When viewed in an XY plane, the traveling rail 100 may have a grid structure.

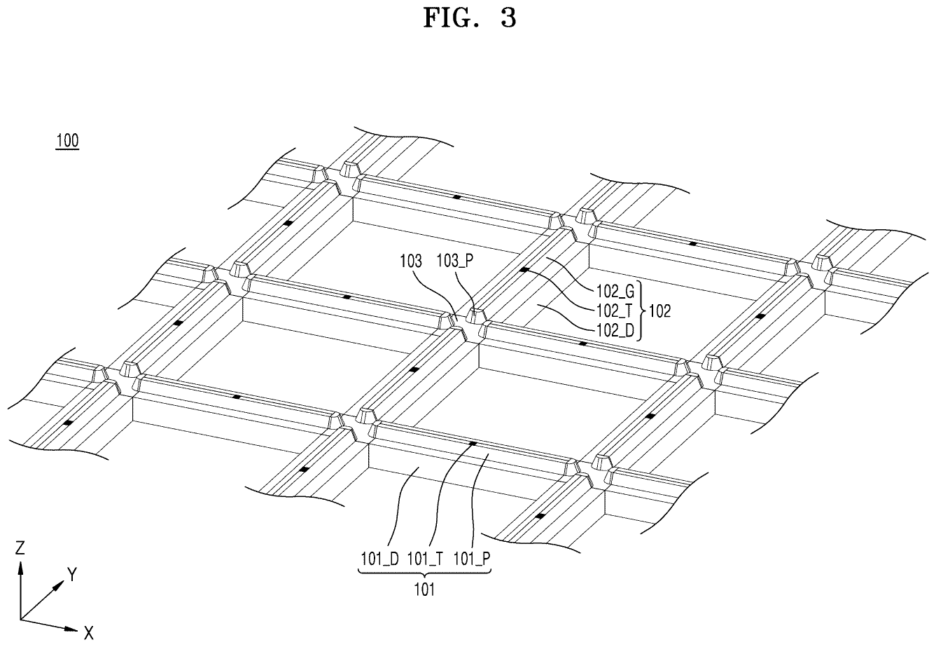

In some embodiments, the article transfer apparatus 1000 may further include a plurality of support columns 300. One end of each of the plurality of support columns 300 may be fastened at an intersection 103 (see FIG. 3) of the traveling rail 100, and the other end may be connected onto the ceiling wall CW. The traveling rail 100 may be fixed to the ceiling wall CW by the plurality of support columns 300.

The transfer robot 200 may be positioned on the traveling rail 100. The transfer robot 200 may hold the article WP and may be in charge of a horizontal transfer and a vertical transfer of the article WP. The transfer robot 200 may transfer the article WP by moving the article WP while holding the article WP from a designated start position of the traveling rail 100 to a designated target position. In addition, the transfer robot 200 may vertically transfer the article WP between the traveling rail 100 and the load ports LP of the facilities MF.

The article transfer apparatus 1000 may simultaneously operate a plurality of transfer robots 200. Each of the plurality of transfer robots 200 is configured to communicate with a higher system, and the operations of the plurality of transfer robots 200 may be controlled by the higher system. The higher system may be referred to as a control part (or a controller).

The higher system (e.g., the controller) may include a memory device such as read only memory (ROM) and random access memory (RAM) in which various programming instructions are stored, and a processor such as a microprocessor, a central processing unit (CPU), a graphics processing unit (GPU) and the like, configured to process programming instructions stored in the memory device and signals provided from the outside. The programming instructions may be configured to, when executed by the processor, cause the higher system to perform its functions. In addition, the higher system may include a receiver and a transmitter for receiving and transmitting electrical signals, respectively.

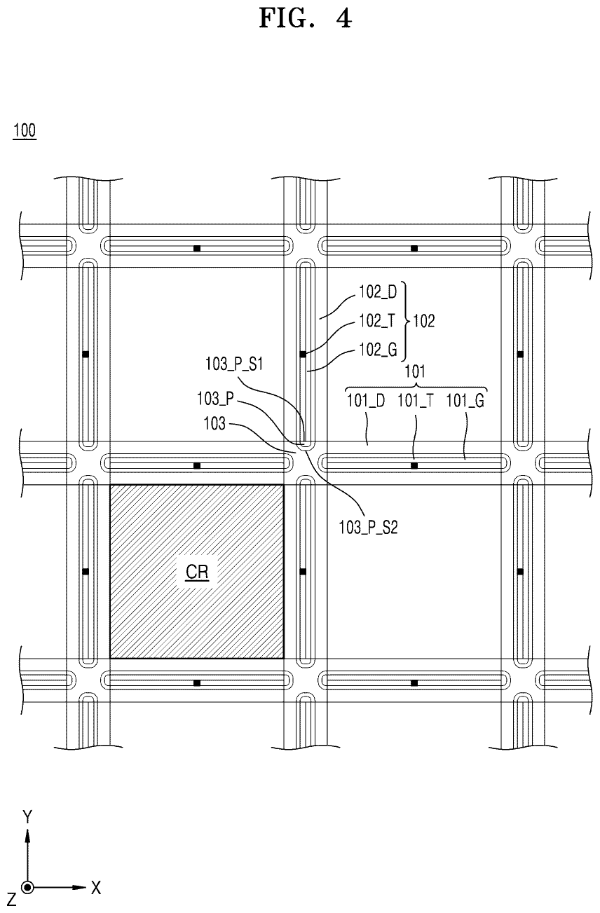

The transfer robot 200 may receive information on a start position and a target position from the higher system, and may move from the start position to the target position based on the information transmitted from the higher system. The start position may be an XY coordinate corresponding to any one of a plurality of cell regions CR (see FIG. 4), and the target position may be an XY coordinate corresponding to another one of the plurality of cell regions. The higher system determines any one from among a plurality of paths extending from a designated start position to a designated target position, and the transfer robot 200 may travel from the start position to the target position along the path transmitted from the higher system.

In some embodiments, the transfer robot 200 searches for the plurality of paths based on the start position and the target position transmitted from the higher system, and may determine an optimized path among the plurality of found paths. When another transfer robot 200 is detected on a path in which the transfer robot 200 travels toward the target position, the transfer robot 200 may be configured to travel according to a bypass path generated by the higher system or the transfer robot 200 itself. Since the traveling rail 100 that has a grid structure generates a plurality of paths between the starting position and the target position, the higher system may generate an optimized path that may minimize the bottleneck of the transfer robot 200 among the plurality of paths.

FIG. 3 is a perspective view schematically showing a part of a traveling rail 100 of an article transfer apparatus 1000 according to an embodiment. FIG. 4 is a plan view schematically illustrating the traveling rail 100 of FIG. 3.

Hereinafter, the traveling rail 100 of the article transfer apparatus 1000 is described in detail with reference to FIGS. 3 and 4 together with FIG. 2. The traveling rail 100 may include a plurality of first rails 101, a plurality of second rails 102, and a plurality of intersections 103.

Each of the plurality of first rails 101 may extend in the first direction (X direction) and may be spaced apart from each other in the second direction (Y direction). Each of the plurality of first rails 101 may include a first traveling part 101_D and a first guide part 101_G. The first traveling part 101_D may extend in the first direction (X direction). The first guide part 101_G may protrude from the top surface of the first traveling part 101_D in the vertical direction (Z direction). For example, the first guide part 101_G may extend lengthwise in the first direction (X direction) along the center of the top surface of the first traveling part 101_D.

Each of the plurality of second rails 102 may extend in the second direction (Y direction) and may be spaced apart from each other in the first direction (X direction). Each of the plurality of second rails 102 may include a second traveling part 102_D and a second guide part 102_G. The second traveling part 102_D may extend lengthwise in the second direction (Y direction). The second guide part 102_G may protrude from the top surface of the second traveling part 102_D in the vertical direction (Z direction). For example, the second guide part 102_G may extend lengthwise in the second direction (Y direction) along the center of the top surface of the second traveling part 102_D.

For example, the traveling rail 100 may include the plurality of cell regions CR defined by the plurality of first rails 101 and the plurality of second rails 102. Each cell region CR may be defined as a region surrounded by two of the first rails 101 adjacent to each other in the second direction (Y direction) among the plurality of first rails 101 and two of the second rails 102 adjacent to each other in the first direction (X direction) among the plurality of second rails 102. Each cell region CR may have a rectangular shape or a square shape in a plan view.

In some embodiments, the horizontal width of the first guide part 101_G of each of the plurality of first rails 101 may narrow as the distance from the top surface of the first traveling part 101_D increases. For example, an angle formed between the top surface of the first guide part 101_G and the side surface of the first guide part 101_G may be greater than 90 degrees and less than 180 degrees.

In some embodiments, the horizontal width of the second guide part 102_G of each of the plurality of second rails 102 may narrow as the distance from the top surface of the second traveling part 102_D increases. For example, an angle formed between the top surface of the second guide part 102_G and the side surface of the second guide part 102_G may be greater than 90 degrees and less than 180 degrees.

Each of the plurality of intersections 103 may be located at an intersection of one of the plurality of first rails 101 and one of the plurality of second rails 102. A vertical level of a top surface of each of the plurality of intersections 103 may be substantially the same as a vertical level of a top surface of the first traveling part 101_D of the plurality of first rails 101 and a vertical level of a top surface of the second traveling part 102_D of the plurality of second rails 102.

Each of the plurality of intersections 103 may include a plurality of protrusions 103_P protruding from a top surface of each of the intersections 103. A vertical level of the top surface of each of the plurality of protrusions 103_P may be substantially the same as a vertical level of the top surface of the first guide part 101_G and a vertical level of the second guide part 102_G.

Some of the plurality of protrusions 103_P may be in contact with the first guide part 101_G of the first rail 101 in contact with the intersection 103, and the rest of the plurality of protrusions 103_P may be in contact with the second guide part 102_G of the second rail 102 in contact with the intersection 103. For example, each of the plurality of intersections 103 may include four protrusions 103_P.

The plurality of protrusions 103_P may guide the traveling wheel 222_D or the guide wheel 222_G of the transfer robot 200 when the transfer robot 200 enters the intersection 103, thereby suppressing vibration occurring in the transfer robot 200.

Each of the plurality of protrusion parts 103_P may include a first side surface 103_P_S1 and a second side surface 103_P_S2 facing a direction opposite of a facing direction of the first side surface 103_P_S1. The first side surface 103_P_S1 of each of the plurality of protrusions 103_P may be a side surface in contact with the first guide part 101_G or the second guide part 102_G. For example, the first side surface 103_P_S1 of each of the plurality of protrusions 103_P may face the outer periphery of the intersection 103.

The second side surface 103_P_S2 of each of the plurality of protrusions 103_P may include a rounded part. For example, the second side surface 103_P_S2 of each of the plurality of protrusions 103_P may include a rounded part such that the second side surface 103_P_S2 comes closer to the first side surface 103_P_S1 towards opposite side surfaces adjacent to the second side surface 103_P_S2. For example, a horizontal width of each of the plurality of protrusions 103_P may narrow as each of the protrusions 103_P approaches the center of the top surface of the intersection 103.

In some embodiments, the horizontal width of each of the plurality of protrusions 103_P may increase as each of the protrusions 103_P approaches the top surface of the intersection 103. For example, based on the protrusion 103_P contacting the first guide part 101_G, the width of the top surface of the protrusion 103_P may be substantially the same as the width of the top surface of the first guide part 101_G, and the width of the bottom surface of the protrusion 103_P may be substantially the same as the width of the bottom surface of the first guide part 101_G.

In some embodiments, the traveling rail 100 may further include a plurality of identification tags. The plurality of identification tags may be a radio frequency identification (RFID) tag, a quick response (QR) code, or a barcode, but are not limited thereto.

The plurality of identification tags may include a first identification tag 101_T and a second identification tag 102_T. For example, the first identification tag 101_T may be located on the top surface of the first guide part 101_G of each of the plurality of first rails 101, and the second identification tag 102_T may be located on the top surface of the second guide part 102_G of each of the plurality of second rails 102.

In some embodiments, the transfer robot 200 may identify the location of the transfer robot 200 based on the first identification tags 101_T located on the plurality of first rails 101 and the second identification tags 102_T located on the plurality of second rails 102. For example, the transfer robot 200 may recognize its own location based on the first identification tag 101_T and the second identification tag 102_T to align the transfer robot 200 and the cell region CR, so that the plurality of guide wheels 222_G of the transfer robot 200 do not contact the first guide part 101_G and the second guide part 102_G when the transfer robot 200 changes its traveling direction.

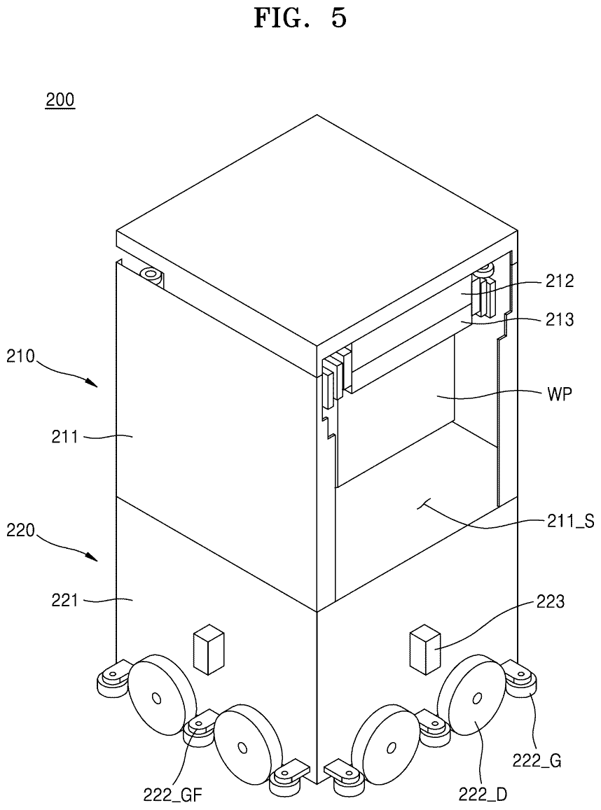

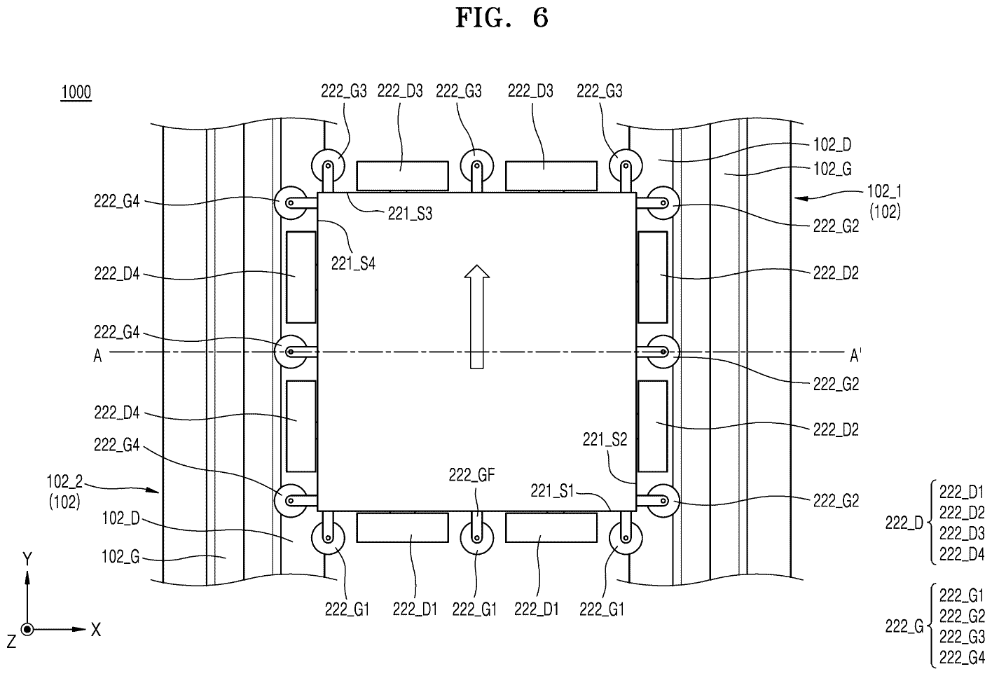

FIG. 5 is a perspective view schematically showing a part of a transfer robot 200 of an article transfer apparatus 1000 according to an embodiment. FIG. 6 is a plan view schematically showing a part of an article transfer apparatus 1000 according to an embodiment.

Hereinafter, the transfer robot 200 of the article transfer apparatus 1000 is described in detail with reference to FIGS. 5 and 6 together with FIGS. 2 and 4. The transfer robot 200 may be positioned on the traveling rail 100, and may include a driving part 220 and a loading part 210.

The loading part 210 of the transfer robot 200 may be configured to hold an article WP and vertically transfer the article WP between the traveling rail 100 and the load ports LP of the facilities MF. The loading part 210 may include a first frame 211, a slide part 212, and a gripper 213.

A loading space 211_S forming an interior of the loading part 210 of the first frame 211 and configured to receive the article WP may be located inside the first frame 211. In some embodiments, a fall prevention structure may be located in the loading space 211_S of the first frame 211. The fall prevention structure supports a side surface of the article WP mounted in the loading space 211_S, thereby preventing the article WP from falling, damaging, and shaking during the transfer of the article WP.

The slide part 212 may be attached to the first frame 211 and may protrude to the outer periphery of the first frame 211. The slide part 212 may protrude in the first direction (X direction) or the second direction (Y direction) with respect to the first frame 211. For example, the slide part 212 may be switched between a standby state located inside the first frame 211 and a protruding state located outside the first frame 211. For example, when the slide part 212 is in a protruding state, the slide part 212 may protrude by the width of the cell region CR with respect to the outer wall of the first frame 211. According to embodiments, the slide part 212 may include at least one body and at least one actuator configured to move the at least one body to and from the standby state and the protruding state.

The gripper 213 may be attached to the slide part 212. For example, one end of the gripper 213 may be attached to a bottom surface of the slide part 212. For example, the gripper 213 may move together as the slide part 212 moves.

A length of the gripper 213 protruding from the bottom surface of the slide part 212 may be changed. As the length of the gripper 213 protruding from the bottom surface of the slide part 212 in the vertical direction (Z direction) is changed, the vertical level of the other end of the gripper 213, opposite of the one end of the gripper 213, may vary. The other end of the gripper 213 may move in the vertical direction (Z direction) between the traveling rail 100 and the load ports LP of the facilities MF.

The gripper 213 may grip and hold the article WP. For example, the gripper 213 may be driven by an actuator and may be configured to switch between a grip state that grips the article WP and an ungrip state that releases the grip on the article WP.

For example, the transfer robot 200 may switch the slide part 212 from the standby state to the protruding state, move the other end of the gripper 213 downward in the vertical direction (Z direction), and then switch the gripper 213 to the grip state to hold the article WP. After the gripper 213 grips the article WP, the transfer robot 200 may move the other end of the gripper 213 upward in the vertical direction (Z direction), switch the slide part 212 into the standby state, and load the article WP in the loading space 211_S of the first frame 211.

For example, the transfer robot 200 may hold the article WP mounted in the loading space 211_S of the first frame 211 with the gripper 213, then switch the slide part 212 from the standby state to the protruding state, move the other end of the gripper 213 downward in the vertical direction (Z direction), and then switch the gripper 213 to the ungrip state to load the article WP into the load port LP.

The driving part 220 of the transfer robot 200 may be configured to travel in the first direction (X direction) or the second direction (Y direction) along the traveling rail 100. For example, traveling of the transfer robot 200 in the first direction (X direction) may be guided by two first rails 101 adjacent to each other in the second direction (Y direction) among the plurality of first rails 101. Traveling of the transfer robot 200 in the second direction (Y direction) may be guided by two second rails 102 adjacent to each other in the first direction (X direction) among the plurality of second rails 102.

The driving part 220 may include a second frame 221, a plurality of traveling wheels 222_D, a plurality of guide wheels 222_G, a driving motor 224, a battery 225, and a wheel elevator 226. The second frame 221 forms the outer shape of the driving part 220, and components may be mounted inside and outside the second frame 221. Although FIG. 2 shows the first frame 211 and the second frame 221 separately, the first frame 211 and the second frame 221 may be one body.

A plurality of traveling wheels 222_D and a plurality of guide wheels 222_G may be positioned at the bottom of the second frame 221. The plurality of traveling wheels 222_D may be configured to travel along a first traveling part 101_D or a second traveling part 102_D, and the plurality of guide wheels 222_G may be configured to prevent the plurality of traveling wheels 222_D from contacting the first guide part 101_G or the second guide part 102_G.

In some embodiments, the plurality of traveling wheels 222_D may include a

first traveling wheel 222_D1, a second traveling wheel 222_D2, a third traveling wheel 222_D3, and a fourth traveling wheel 222_D4. Each of the first traveling wheel 222_D1 and the third traveling wheel 222_D3 may have a rotating axis in the second direction (Y direction), and each of the second traveling wheel 222_D2 and the fourth traveling wheel 222_D4 may have a rotating axis in the first direction (X direction). The first traveling wheel 222_D1 and the third traveling wheel 222_D3 may be spaced apart from each other in the second direction (Y direction). The second traveling wheel 222_D2 and the fourth traveling wheel 222_D4 may be spaced apart from each other in the first direction (X direction).

For example, when the second traveling wheel 222_D2 is located on the second rail 102_1 on one side of the transfer robot 200, the fourth traveling wheel 222_D4 may be located on the second rail 102_2, adjacent to the second rail 102_1, on an opposite side of the of the transfer robot 200.

For example, while the transfer robot 200 travels in the first direction (X direction), the first traveling wheel 222_D1 and the third traveling wheel 222_D3 may move on two neighboring ones of the first rails 101 among the plurality of first rails 101. While the transfer robot 200 travels in the second direction (Y direction), the second traveling wheel 222_D2 and the fourth traveling wheel 222_D4 may move on two neighboring ones of the second rails 102 among the plurality of second rails 102.

Although FIG. 6 illustrates that the transfer robot 200 includes two first traveling wheels 222_D1, two second traveling wheels 222_D2, two third traveling wheels 222_D3, and two fourth traveling wheels 222_D4, the number of first traveling wheels 222_D1, the number of second traveling wheels 222_D2, the number of third traveling wheels 222_D3, and the number of fourth traveling wheels 222_D4 are not limited thereto.

The direction of the rotating axis of each of the plurality of guide wheels 222_G may be a vertical direction (Z direction). For example, an outer circumferential surface of each of the plurality of guide wheels 222_G may be a side surface of each of the plurality of guide wheels 222_G. While the transfer robot 200 is traveling on the traveling rail 100, some of the plurality of guide wheels 222_G may be in contact with at least one from among the first guide part 101_G and the second guide part 102_G.

The plurality of guide wheels 222_G may include at least one first guide wheel 222_G1, at least one second guide wheel 222_G2, at least one third guide wheel 222_G3, and at least one fourth guide wheel 222_G4. The first guide wheel 222_G1 may be spaced apart from the first traveling wheel 222_D1 in the first direction (X direction), the second guide wheel 222_G2 may be spaced apart from the second traveling wheel 222_D2 in the second direction (Y direction), the third guide wheel 222_G3 may be spaced apart from the third traveling wheel 222_D3 in the first direction (X direction), and the fourth guide wheel 222_G4 may be spaced apart from the fourth traveling wheel 222_D4 in the second direction (Y direction).

For example, the second frame 221 may include a first side surface 221_S1, a second side surface 221_S2 adjacent to the first side surface 221_S1, a third side surface 221_S3 facing away from the first side surface 221_S1 and adjacent to the second side surface 221_S2, and a fourth side surface 221_S4 facing away from the second side surface 221_S2 and adjacent to the first side surface 221_S1.

The first traveling wheel 222_D1 and the first guide wheel 222_G1 may be located on the first side surface 221_S1 of the second frame 221, the second traveling wheel 222_D2 and the second guide wheel 222_G2 may be located on the second side surface 221_S2 of the second frame 221, the third traveling wheel 222_D3 and the third guide wheel 222_G3 may be located on the third side surface 221_S3 of the second frame 221, and the fourth traveling wheel 222_D4 and the fourth guide wheel 222_G4 may be located on the fourth side surface 221_S4 of the second frame 221.

In some embodiments, a partial region of the outer circumferential surface of the first guide wheel 222_G1 may protrude to the outer periphery of the transfer robot 200 past the outer side surface of the first traveling wheel 222_D1. A partial region of the outer circumferential surface of the second guide wheel 222_G2 may protrude to the outer periphery of the transfer robot 200 past the outer side surface of the second traveling wheel 222_D2. A partial region of the outer circumferential surface of the third guide wheel 222_G3 may protrude to the outer periphery of the transfer robot 200 past the outer side surface of the third traveling wheel 222_D3. A partial region of the outer circumferential surface of the fourth guide wheel 222_G4 may protrude to the outer periphery of the transfer robot 200 past the outer side surface of the fourth traveling wheel 222_D4. The outer side surface of each of the plurality of traveling wheels 222_D means a side surface farthest from the second frame 221 among side surfaces of each of the plurality of traveling wheels 222_D.

In some embodiments, the maximum separation distance between the outer circumferential surface of the first guide wheel 222_G1 and the first side surface 221_S1 of the second frame 221 may be greater than the separation distance between the outer side surface of the first traveling wheel 222_D1 and the first side surface 221_S1 of the second frame 221. The plurality of guide wheels 222_G may suppress a phenomenon in which the plurality of traveling wheels 222_D are in direct contact with the first guide part 101_G or the second guide part 102_G.

In some embodiments, the plurality of guide wheels 222_G may include a plurality of first guide wheels 222_G1, a plurality of second guide wheels 222_G2, a plurality of third guide wheels 222_G3, and a plurality of fourth guide wheels 222_G4. The plurality of first guide wheels 222_G1 may be spaced apart from each other with the first traveling wheel 222_D1 therebetween. The plurality of second guide wheels 222_G2 may be spaced apart from each other with the second traveling wheel 222_D2 therebetween. The plurality of third guide wheels 222_G3 may be spaced apart from each other with the third traveling wheel 222_D3 therebetween. The plurality of fourth guide wheels 222_G4 may be spaced apart from each other with the fourth traveling wheel 222_D4 therebetween. The transfer robot 200 includes the plurality of first guide wheels 222_G1, the plurality of second guide wheels 222_G2, the plurality of third guide wheels 222_G3, and the plurality of fourth guide wheels 222_G4, and thus may suppress a phenomenon in which the transfer robot 200 rotates in the vertical direction (Z direction) as a rotating axis.

While the transfer robot 200 travels on the traveling rail 100, the transfer robot 200 may be biased to one side of the transfer robot 200 by the center of gravity of the transfer robot 200 or the shaking of the transfer robot 200. For example, while the transfer robot 200 travels in the first direction (X direction) along two neighboring ones of the first rails 101 among the plurality of first rails 101, the transfer robot 200 may be relatively biased to one of the two neighboring ones of the first rails 101. When the transfer robot 200 is biased to one side, the plurality of guide wheels 222_G may suppress a phenomenon in which the plurality of traveling wheels 222_D are in direct contact with the first guide part 101_G or the second guide part 102_G.

In some embodiments, the horizontal width of each of the plurality of guide wheels 222_G may narrow downward in the vertical direction (Z direction). For example, the diameter of the outer circumferential surface of each of the plurality of guide wheels 222_G may decrease toward a bottom surface of each of the plurality of guide wheels 222_G.

For example, while the transfer robot 200 travels in the first direction (X direction), at least one from among the first guide wheel 222_G1 and the third guide wheel 222_G3 may be in contact with the first guide part 101_G of at least one of the plurality of first rails 101, and while the transfer robot 200 travels in the second direction (Y direction), at least one from among the second guide wheel 222_G2 and the fourth guide wheel 222_G4 may be in contact with the second guide part 102_G of at least one of the plurality of second rails 102.

The driving motor 224 may be connected to the plurality of traveling wheels 222_D to provide driving power to the plurality of traveling wheels 222_D. The battery 225 may provide power to the driving motor 224. The plurality of guide wheels 222_G may rotate in contact with the first guide part 101_G or the second guide part 102_G as the plurality of traveling wheels 222_D move along the traveling rail 100.

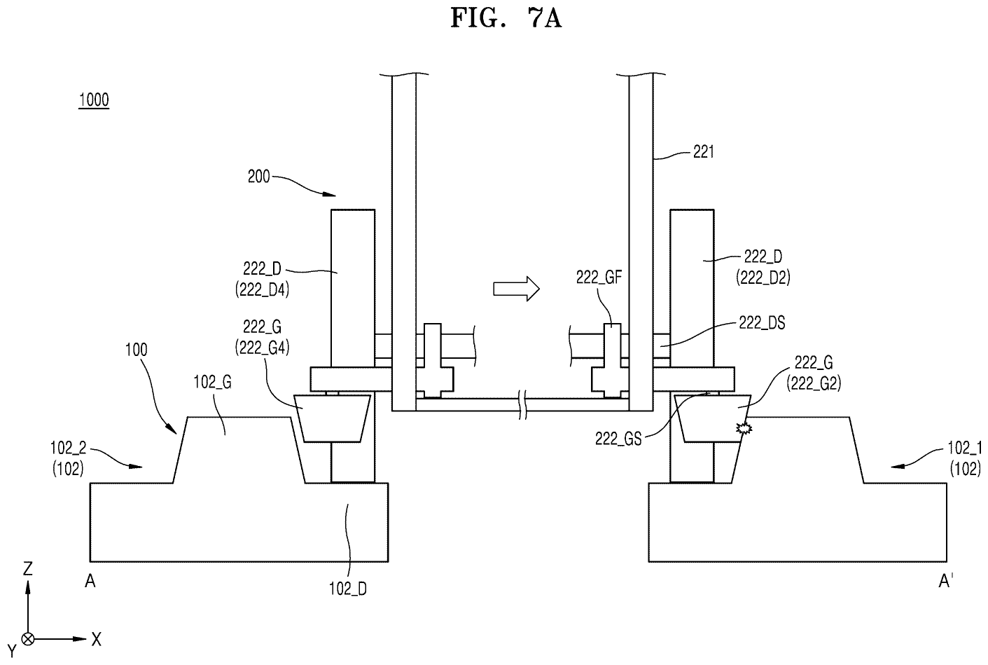

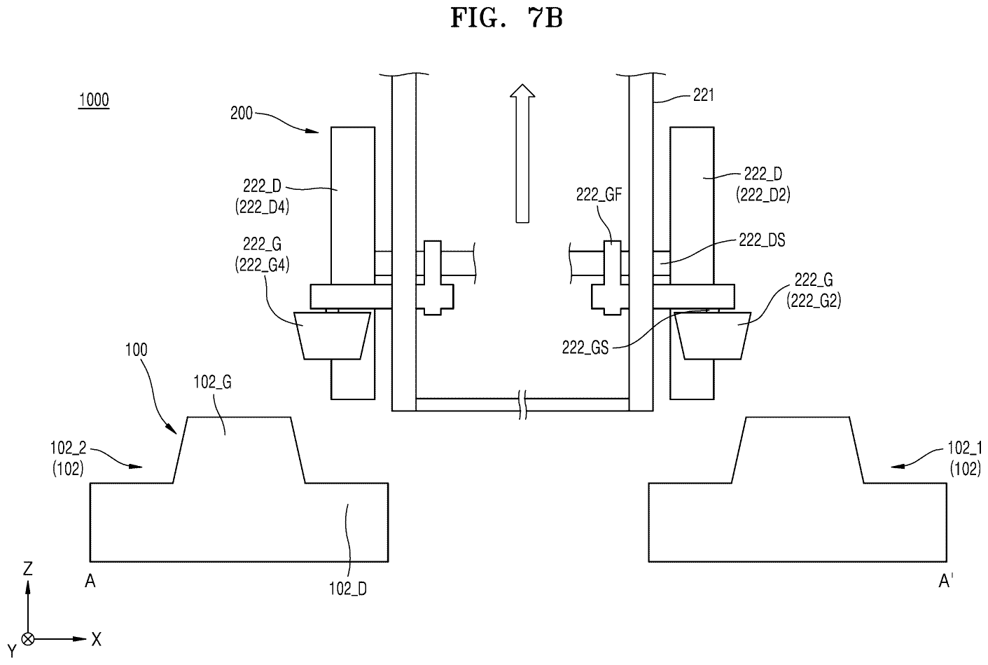

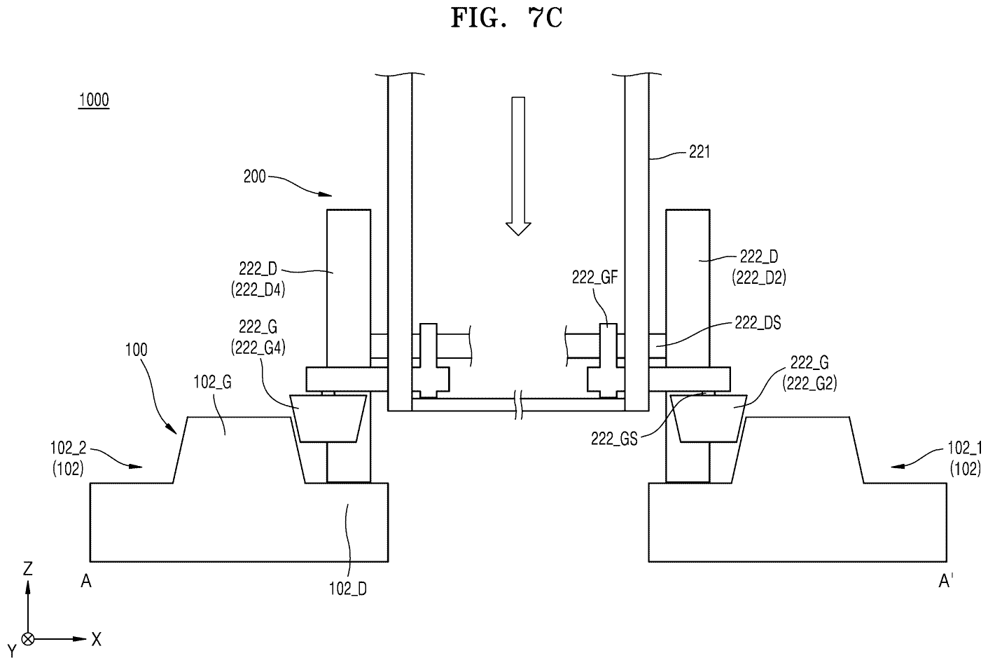

The wheel elevator 226 may be configured to move the plurality of traveling wheels 222_D in the vertical direction (Z direction) so that some of the plurality of traveling wheels 222_D are in contact with or spaced apart from the traveling rail 100. For example, the wheel elevator 226 may move the plurality of traveling wheels 222_D relative to the second frame 221. For example, the wheel elevator 226 may include an actuator fixed to the second frame 221 to move power shafts 222_DS (see FIG. 7A) of the plurality of traveling wheels 222_D in the vertical direction.

The wheel elevator 226 may simultaneously move, in the vertical direction, the traveling wheels 222_D having the same direction of the rotating axis among the plurality of traveling wheels 222_D. For example, the wheel elevator 226 may be configured to simultaneously raise or lower the first traveling wheel 222_D1 and the third traveling wheel 222_D3, and to raise or lower the second traveling wheel 222_D2 and the fourth traveling wheel 222_D4.

In some embodiments, the plurality of guide wheels 222_G may be configured to move in the vertical direction (Z direction) together with the traveling wheel 222_D moving in the vertical direction (Z direction) while the traveling wheel 222_D is moved in the vertical direction (Z direction) by the wheel elevator 226. The guide wheel 222_G located on the rail where the traveling wheel 222_D that rises or falls among the plurality of guide wheels 222_G is located may be configured to rise or fall together with the traveling wheel 222_D that rises or falls.

In some embodiments, when the first traveling wheel 222_D1 moves in the vertical direction (Z direction), the first guide wheel 222_G1 may move in the vertical direction (Z direction) together with the first traveling wheel 222_D1. When the second traveling wheel 222_D2 moves in the vertical direction (Z direction), the second guide wheel 222_G2 may move in the vertical direction (Z direction) together with the second traveling wheel 222_D2. When the third traveling wheel 222_D3 moves in the vertical direction (Z direction), the third guide wheel 222_G3 may move in the vertical direction (Z direction) together with the third traveling wheel 222_D3. When the fourth traveling wheel 222_D4 moves in the vertical direction (Z direction), the fourth guide wheel 222_G4 may move in the vertical direction (Z direction) together with the fourth traveling wheel 222_D4.

In some embodiments, each of the plurality of guide wheels 222_G may be attached to a fixed structure 222_GF by a shaft 222_GS (see FIG. 7A), and the fixed structure 222_GF may be attached to a power shaft 222_DS (see FIG. 7A) of the plurality of traveling wheels 222_D by a bearing. Accordingly, when the traveling wheel 222_D is moved in the vertical direction (Z direction) by the wheel elevator 226, as the fixed structure 222_GF attached to the power shaft 222_DS moves in the vertical direction (Z direction) together with the power shaft 222_DS, the plurality of guide wheels 222_G attached to the fixed structure 222_GF may move in the vertical direction (Z direction). However, a method in which the plurality of guide wheels 222_G move together with the plurality of traveling wheels 222_D is not limited thereto.

In some embodiments, the transfer robot 200 may further include at least one tag reader 223 (e.g., a sensor). The tag reader 223 may sense an identification tag provided on the traveling rail 100. The tag reader 223 may recognize the identification tag of the traveling rail 100 to check the location of the transfer robot 200, the distance between the transfer robot 200 and the traveling rail 100, and the like. For example, the tag reader 223 may be an optical sensor.

Referring to FIGS. 2 and 6, a traveling and a traveling direction changing method of the transfer robot 200 are described in detail.

As shown in FIG. 2, in the case of a transfer robot 200x traveling in the first direction (X direction), the traveling wheels 222_D in which the direction of the rotating axis is the first direction (X direction) (e.g., the second traveling wheel 222_D2 and the fourth traveling wheel 222_D4) may be in a raised state in the vertical direction (Z direction) so as to be spaced apart from the second rail 102 in the vertical direction (Z direction). Accordingly, while the transfer robot 200 travels on the first rails 101, it is possible to suppress a phenomenon in which the plurality of traveling wheels 222_D, particularly, the second traveling wheel 222_D2 and the fourth traveling wheel 222_D4, collide with the second guide part 102_G of the second rail 102.

For example, in the case of the transfer robot 200x traveling in the first direction (X direction), the vertical level of each of the bottom surfaces of the first guide wheel 222_G1 and the third guide wheel 222_G3 may be higher than the vertical level of the top surface of the first traveling part 101_D of each of the plurality of first rails 101 and lower than the vertical level of the top surface of the first guide part 101_G. The first guide wheel 222_G1 may prevent the first traveling wheel 222_D1 from being in contact with the first guide part 101_G, and the third guide wheel 222_G3 may prevent the third traveling wheel 222_D3 from being in contact with the first guide part 101_G.

As shown in FIG. 2, in the case of a transfer robot 200y traveling in the second direction (Y direction), the traveling wheels 222_D in which the direction of the rotating axis is the second direction (Y direction) (e.g., the first traveling wheel 222_D1 and the third traveling wheel 222_D3) may be in a raised state in the vertical direction (Z direction) so as to be spaced apart from the first rail 101 in the vertical direction (Z direction). Accordingly, while the transfer robot 200 travels on the second rails 102, it is possible to suppress a phenomenon in which the plurality of traveling wheels 222_D, particularly, the first traveling wheel 222_D1 and the third traveling wheel 222_D3, collide with the first guide part 101_G on the first rails 101.

For example, in the case of the transfer robot 200y traveling in the second direction (Y direction), the vertical level of the bottom surface of the first guide wheel 222_G1 and the vertical level of the outer circumferential surface of the first traveling wheel 222_D1 may be higher than the vertical level of the top surface of the first guide part 101_G on the plurality of first rails 101. When the transfer robot 200 travels on the plurality of second rails 102, a phenomenon in which the first guide wheel 222_G1 and the first traveling wheel 222_D1 collide with the first guide part 101_G on the plurality of first rails 101 may be suppressed.

In the process of changing the traveling direction of the transfer robot 200, the plurality of traveling wheels 222_D may move in the vertical direction (Z direction). For example, among the plurality of traveling wheels 222_D, the traveling wheels 222_D that are spaced apart from the traveling rail 100 may be lowered to contact the traveling rail 100, and the traveling direction of the transfer robot 200 may be changed by raising the traveling wheels 222_D that are in contact with the traveling rail 100.

For example, a process of changing the traveling direction of the transfer robot 200 from the first direction (X direction) to the second direction (Y direction) is described below. The transfer robot 200 traveling in the first direction (X direction) while the second traveling wheel 222_D2 and the fourth traveling wheel 222_D4 are raised may be aligned in one of the plurality of cell regions CR. Thereafter, the transfer robot 200 may lower the second traveling wheel 222_D2 and the fourth traveling wheel 222_D4 so that the plurality of second rails 102 are in contact with the second traveling wheel 222_D2 and the fourth traveling wheel 222_D4. Thereafter, the first traveling wheel 222_D1 and the third traveling wheel 222_D3 may be raised so that the first traveling wheel 222_D1 and the third traveling wheel 222_D3 are spaced apart from the plurality of first rails 101. Thereafter, the transfer robot 200 may travel in the second direction (Y direction) along the plurality of second rails 102.

FIGS. 7A to 7C are cross-sectional views schematically showing the article transfer apparatus 1000 of FIG. 5, which is taken along a line A-A′ of FIG. 6. Specifically, FIG. 7A shows that the transfer robot 200 travels in the second direction (Y direction), FIG. 7B shows that the second traveling wheel 222_D2 and the fourth traveling wheel 222_D4 of the transfer robot 200 are raised, and FIG. 7C shows that the second traveling wheel 222_D2 and the fourth traveling wheel 222_D4 of the transfer robot 200 are lowered.

Hereinafter, the ascending and descending of the plurality of guide wheels 222_G of the transfer robot 200 will be described with reference to FIGS. 2, 4, and 6 together with FIGS. 7A to 7C. The relationship between the traveling rail 100, the traveling wheel 222_D, and the guide wheel 222_G is described based on a state in which the transfer robot 200 travels in the second direction (Y direction), but the relationship may be substantially the same even in a state in which the transfer robot 200 travels in the first direction (X direction).

Referring to FIG. 7A, when the transfer robot 200 travels in the second direction (Y direction), the transfer robot 200 may be biased to one side by the center of gravity of the transfer robot 200 and the article WP loaded on the transfer robot 200. For example, while the transfer robot 200 travels along two neighboring ones of the second rails 102 among the plurality of second rails 102, the transfer robot 200 may be biased to one of the second rails 102_1.

Accordingly, the second guide wheel 222_G2 located on the second rail 102_1 at one side of the transfer robot 200 may be in contact with the second guide part 102_G of the second rail 102_1. However, the fourth guide wheel 222_G4 may be spaced apart from the second guide part 102_G of the second rail 102_2 on the opposite side of the transfer robot 200.

Referring to FIG. 7B, a process is shown in which the transfer robot 200 raises the traveling wheels 222_D of which the direction of the rotating axis is the first direction (X direction) among the plurality of traveling wheels 222_D to change the traveling direction of the transfer robot 200. For example, in the process of raising the second traveling wheel 222_D2 and the fourth traveling wheel 222_D4, the second guide wheel 222_G2 and the fourth guide wheel 222_G4 may be raised together. For example, as the second traveling wheel 222_D2 ascends, the second guide wheel 222_G2 may be switched from a state of being in contact with the second guide part 102_G of the second rail 102_1 to a state of being spaced apart from each other.

As each of the first guide parts 101_G of the plurality of first rails 101 and each of the second guide parts 102_G of the plurality of second rails 102 goes upward in the vertical direction (Z direction), the horizontal width thereof may narrow. The horizontal width of each of the plurality of guide wheels 222_G may narrow downward in the vertical direction.

Accordingly, when the plurality of guide wheels 222_G are spaced apart from the first guide part 101_G or the second guide part 102_G, a relatively small friction force may occur between the plurality of guide wheels 222_G and the first guide parts 101_G or between the plurality of guide wheel 222_G and the second guide parts 102_G. For example, when the second guide wheel 222_G2 is spaced apart from the second guide part 102_G2 of the second rail 102_1 as the second traveling wheel 222_D2 ascends, the frictional length and normal force between the outer circumferential surface of the second guide wheel 222_G2 and the inner side wall of the second guide part 102_G may be relatively small.

Friction generated between the plurality of guide wheels 222_G and the traveling rail 100 is reduced, and thus generation of particles may be suppressed, and a phenomenon in which the plurality of guide wheels 222_G are peeled off from the shaft 222_GS may be suppressed.

In some embodiments, an angle formed by a top surface of the first guide part 101_G and a side surface of the first guide part 101_G of each of the plurality of first rails 101 may be a first angle, an angle formed by a top surface of the second guide part 102_G and the side surface of the second guide part 102_G of each of the plurality of second rails 102 may be a second angle, and an angle formed by a bottom surface of each of the plurality of guide wheels 222_G and the outer circumferential surface of each of the plurality of guide wheels 222_G may be a third angle.

Each of the first angle, the second angle, and the third angle may be obtuse. For example, the first angle, the second angle, and the third angle may be greater than 90 degrees. In some embodiments, the first angle, the second angle, and the third angle may be substantially the same as each other.

Referring to FIG. 7C, a process in which the transfer robot 200 descends the traveling wheels 222_D of which the direction of the rotating axis is the first direction (X direction) among the plurality of traveling wheels 222_D is shown in order to change the traveling direction. For example, in the process of lowering the second traveling wheel 222_D2 and the fourth traveling wheel 222_D4, the second guide wheel 222_G2 and the fourth guide wheel 222_G4 may be lowered together.

A separation distance between the second guide parts 102_G of the two neighboring ones of the second rails 102 among the plurality of second rails 102 in the first direction (X direction) may be greater than a separation distance in the first direction (X direction) between the outer circumferential surface of the second guide wheel 222_G2 and the outer circumferential surface of the fourth guide wheel 222_G4. A separation distance between the first guide parts 101_G of the two neighboring ones of the first rails 101 among the plurality of first rails 101 may be greater than a separation distance in the second direction (Y direction) between an outer circumferential surface of the first guide wheel 222_G1 and an outer circumferential surface of the third guide wheel 222_G3.

For example, when the plurality of traveling wheels 222_D are in contact with the plurality of second rails 102, at the same vertical level, a separation distance between an inner surface of the second guide part 102_G of the second rail 102_1 on one side of the transfer robot 200 and an inner surface of the second guide part 102_G of the second rail 102_2 on the other side of the transfer robot 200 may be greater than the maximum separation distance in the first direction (X direction) between an outer circumferential surface of the second guide wheel 222_G2 and an outer circumferential surface of the fourth guide wheel 222_G4. An inner side surface of each guide part of the adjacent rails means a side surface of the guide part that is adjacent to the transfer robot 200.

For example, when the center between the second guide parts 102_G of two adjacent ones of the second rails 102 and the center between the outer circumferential surface of the second guide wheel 222_G2 and the fourth guide wheel 222_G4 are positioned on a straight line, the second guide wheel 222_G2 and the fourth guide wheel 222_G4 may not be in contact with the second guide parts 102_G of the plurality of second rails 102. When the transfer robot 200 is not biased to one side, the plurality of guide wheels 222_G may not be in contact with the first guide part 101_G or the second guide part 102_G.

The transfer robot 200 precisely aligns the cell region CR of the traveling rail 100 and the transfer robot 200 using the tag reader 223, so that a phenomenon in which friction occurs between the plurality of guide wheels 222_G and the traveling rail 100 may be suppressed while the plurality of guide wheels 222_G of the transfer robot 200 descend.

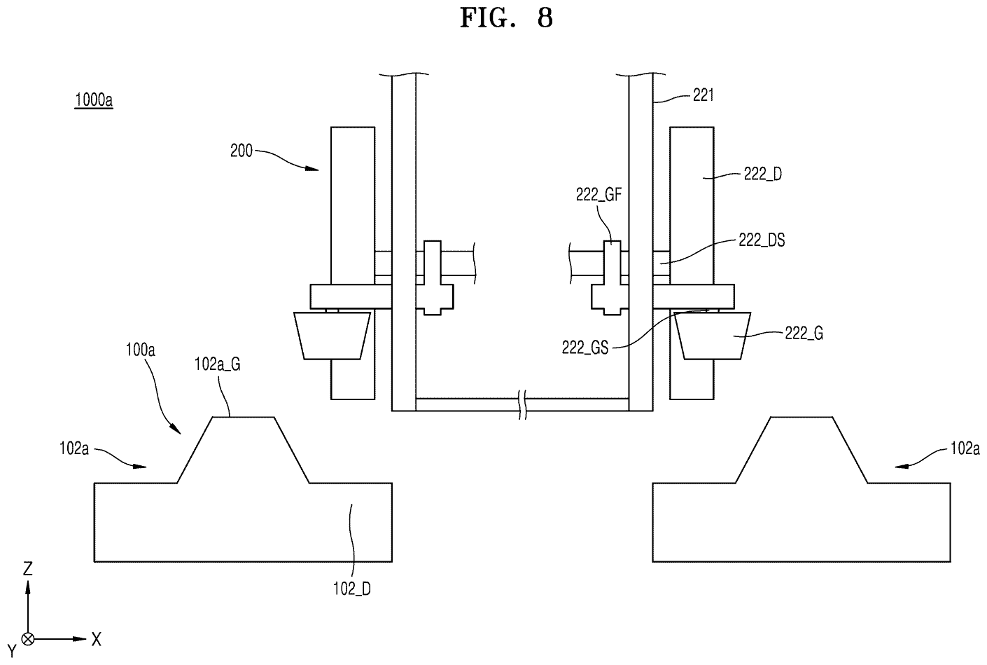

FIG. 8 is a cross-sectional view schematically illustrating a cutaway of an article transfer apparatus 1000a according to an embodiment.

Most of components constituting the article transfer apparatus 1000a described below and the materials constituting the components are substantially the same as or similar to those described above with reference to FIGS. 1 to 6. Therefore, for convenience of explanation, differences between the article transfer apparatus 1000a of FIG. 8 and the article transfer apparatus 1000 of FIG. 2 are mainly described.

The article transfer apparatus 1000a may include a traveling rail 100a and a transfer robot 200. The transfer robot 200 may be substantially the same as the transfer robot 200 described above.

Referring to FIGS. 4 and 8, the traveling rail 100a may include a plurality of first rails 101, a plurality of second rails 102a, and a plurality of intersections 103. FIG. 8 is a view schematically illustrating a cutaway of a part of a plurality of second rails 102a. Hereinafter, with respect to the traveling rail 100a, the plurality of second rails 102a are mainly described, but the plurality of first rails 101 may also be substantially the same.

The plurality of first rails 101 may extend in the first direction (X direction) and may be spaced apart from each other in the second direction (Y direction). Each of the plurality of first rails 101 may include a first traveling part 101_D extending in the first direction (X direction), and a first guide part 101_G protruding upward from a top surface of the first traveling part 101_D.

The plurality of second rails 102a may extend in the second direction (Y direction) and may be spaced apart from each other in the first direction (X direction). Each of the plurality of second rails 102a may include a second traveling part 102_D extending in the second direction (Y direction), and a second guide part 102a_G protruding upward from a top surface of the second traveling part 102_D.

The horizontal width of the first guide part 101_G of each of the plurality of first rails 101 may increase as the first guide part 101_G approaches a top surface of the first traveling part 101_D. The horizontal width of the second guide part 102a_G of each of the plurality of second rails 102a may increase as the second guide part 102a_G approaches a top surface of the second traveling part 102_D. For example, the length of the first guide part 101_G in the second direction (Y direction) may decrease as the first guide part 101_G ascends in the vertical direction (Z direction), and the length of the second guide part 102a_G in the first direction (X direction) may decrease as the second guide part 102a_G ascends in the vertical direction (Z direction).

An angle formed by a side surface of the second guide part 102a_G and a top surface of the second guide part 102a_G may be different from an angle formed by an outer circumferential surface of each of the plurality of guide wheels 222_G and a bottom surface of each of the plurality of guide wheels 222_G. For example, an angle formed by an outer circumferential surface of the second guide part 102a_G and a top surface of the second guide part 102a_G may be greater than an angle formed by an outer circumferential surface of each of the plurality of guide wheels 222_G and a bottom surface of each of the plurality of guide wheels 222_G. For example, a slope of a side surface of the second guide part 102a_G may be gentler than a slope of an outer circumferential surface of each of the plurality of guide wheels 222_G.

Although FIG. 8 illustrates the shape of the second guide part 102a_G of each of the plurality of second rails 102a, the shapes of the first guide part 101_G of each of the plurality of first rails 101 and the second guide part 102a_G of each of the plurality of second rails 102a may be substantially the same. An angle formed by a side surface of the first guide part 101_G and a top surface of the first guide part 101_G may be greater than an angle formed by an outer circumferential surface of each of the plurality of guide wheels 222_G and a bottom surface of each of the plurality of guide wheels 222_G.

For example, the plurality of guide wheels 222_G may include an elastic material such as urethane. When the plurality of guide wheels 222_G are in contact with the first guide part 101_G or the second guide part 102a_G, the outer circumferential surfaces of the plurality of guide wheels 222_G may be elastically deformed according to the shape of the side surface of the first guide part 101_G or the second guide part 102a_G. In the process of switching a state in which the plurality of guide wheels 222_G are in contact with the first guide part 101_G or the second guide part 102a_G to a state in which the former is spaced apart from the latter, a slope of a side surface of the second guide part 102a_G is gentler than a slope of an outer circumferential surface of each of the plurality of guide wheels 222_G, and thus the time for friction occurring between the plurality of guide wheels 222_G and the second guide part 102a_G may be reduced.

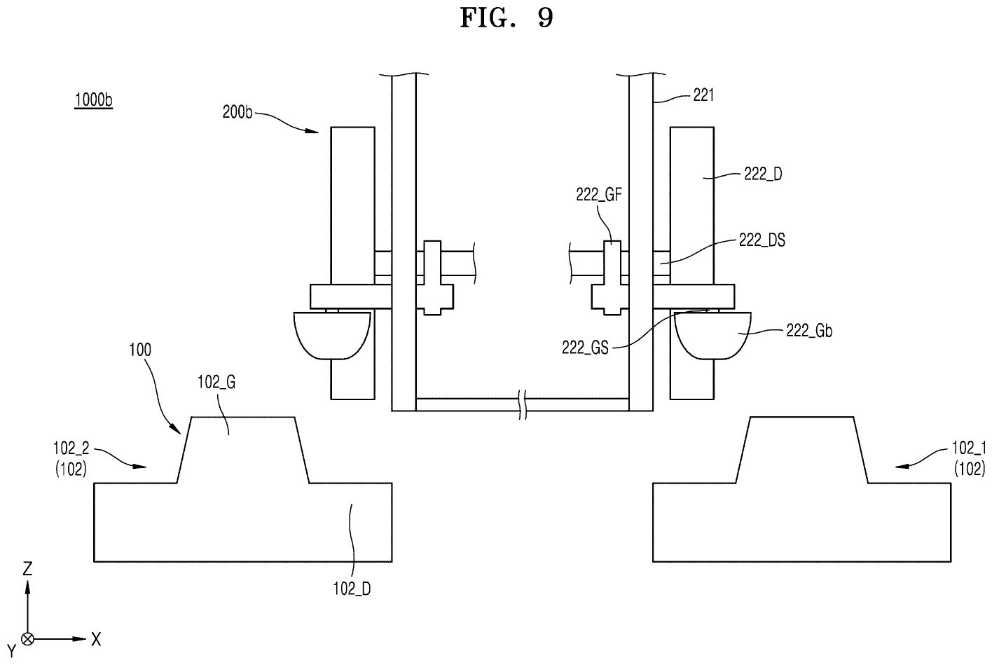

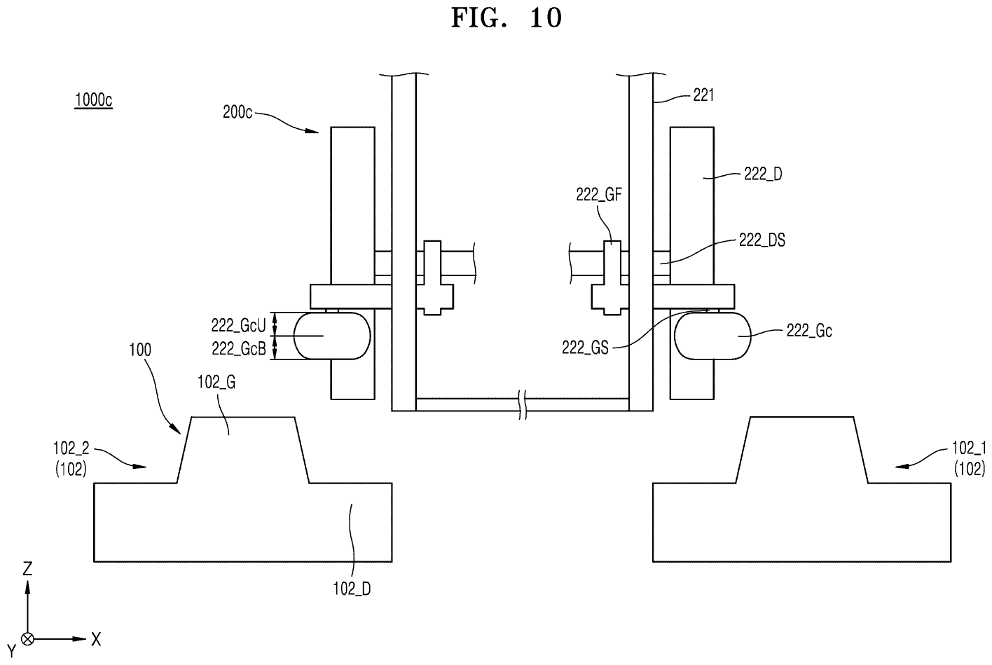

FIG. 9 is a cross-sectional view schematically illustrating a cutaway of an article transfer apparatus 1000b according to an embodiment. FIG. 10 is a cross-sectional view schematically illustrating a cutaway of an article transfer apparatus 1000c according to an embodiment.

Most of components constituting the article transfer apparatuses 1000b and 1000c described below and the materials constituting the components are substantially the same as or similar to those described above with reference to FIGS. 1 to 6. Therefore, for convenience of explanation, differences between the article transfer apparatuses 1000b and 1000c of FIGS. 9 and 10 and the article transfer apparatus 1000 of FIG. 2 are mainly described below.

Referring to FIG. 9 together with FIG. 5, an article transfer apparatus 1000b may include a traveling rail 100 and a transfer robot 200b. The traveling rail 100 may be substantially the same as the traveling rail 100 described above.

The transfer robot 200b may include a loading part 210 (see FIG. 2) and a driving part 220 (see FIG. 2) The driving part 220 (see FIG. 2) may include a plurality of traveling wheels 222_D and a plurality of guide wheels 222_Gb. Some of the plurality of traveling wheels 222_D may each have a rotating axis in the first direction (X direction), and the rest of the plurality of traveling wheels 222_D may each have a rotating axis in the second direction (Y direction). The direction of the rotating axis of each of the plurality of guide wheels 222_Gb may be a vertical direction (Z direction).

Each of the plurality of traveling wheels 222_D may be connected to a power shaft 222_DS of which the extension direction is the same as the direction of the rotating axis of each of the plurality of traveling wheels 222_D, and each of the plurality of guide wheels 222_Gb may be connected to a shaft 222_GS of which the extension direction is the vertical direction (Z direction). The power shaft 222_DS and the shaft 222_GS may be connected to each other through a fixed structure 222_GF.

The horizontal width of each of the plurality of guide wheels 222_Gb may narrow downward in the vertical direction (Z direction). For example, a diameter of an outer circumferential surface of each of the plurality of guide wheels 222_Gb may decrease towards a bottom surface of each of the plurality of guide wheels 222_Gb.

An outer circumferential surface of each of the plurality of guide wheels 222_Gb may include a rounded part. For example, the outer circumferential surface of each of the plurality of guide wheels 222_Gb may include a rounded part that approaches the center of a bottom surface of each of the plurality of guide wheels 222_Gb towards the bottom surface of each of the plurality of guide wheels 222_Gb.

Referring to FIG. 10 together with FIG. 5, an article transfer apparatus 1000c may include a traveling rail 100 and a transfer robot 200c. The traveling rail 100 may be substantially the same as the traveling rail 100 described above.

The transfer robot 200c may include a loading part 210 (see FIG. 2) and a driving part 220 (see FIG. 2). The driving part 220 (see FIG. 2) may include a plurality of traveling wheels 222_D and a plurality of guide wheels 222_Gc.

Each of the plurality of guide wheels 222_Gc may have a rotating axis in the vertical (Z direction), and a top surface of each of the plurality of guide wheels 222_Gc may be connected to a shaft 222_GS of which the extension direction is the vertical direction (Z direction).

An outer circumferential surface of each of the plurality of guide wheels 222_Gc may be convex outward. For example, each of the plurality of guide wheels 222_Gc is divided into an upper region 222_GcU and a lower region 222_GcB, and the upper region 222_GcU of each of the plurality of guide wheels 222_Gc is a region in which the horizontal width of each of the plurality of guide wheels 222_Gc gradually increases downward in the vertical direction (Z direction), and the lower region 222_GcB of each of the plurality of guide wheels 222_Gc may be a region in which the horizontal width of each of the plurality of guide wheels 222_Gc gradually decreases downward in the vertical direction (Z direction).

According to embodiments of the present disclosure, a controller may be configured to control the transfer robot (e.g., the transfer robot 200) to perform its functions. For example, the controller may control components (e.g., the driving motor 224, the battery 225, the wheel elevator 226, the slide part 212, the gripper 213, etc.) of the transfer robot (e.g., the transfer robot 200) to perform their respective functions. For example, the controller may cause methods (e.g., a traveling and a traveling direction changing method) of embodiments of the present disclosure to be performed.

According to embodiments of the present disclosure, all or a part of the controller may be included in the transfer robot (e.g., the transfer robot 200) and/or the higher system.

According to embodiments of the present disclosure, the controller may include a memory device such as read only memory (ROM) and random access memory (RAM) in which various programming instructions are stored, and a processor such as a microprocessor, a central processing unit (CPU), a graphics processing unit (GPU) and the like, configured to process programming instructions stored in the memory device and signals provided from the outside. The programming instructions may be configured to, when executed by the processor, cause the controller to perform its functions. In addition, the controller may include a receiver and a transmitter for receiving and transmitting electrical signals, respectively.

While non-limiting example embodiments of the present disclosure have been particularly shown and described, it will be understood that various changes in form and details may be made therein without departing from the spirit and scope of the present disclosure.

What is claimed is:

1. An article transfer apparatus comprising:
a traveling rail comprising:
first rails extending in a first direction and spaced apart from each other in a second direction perpendicular to the first direction; and
second rails extending in the second direction and spaced apart from each other in the first direction; and
a transfer robot on the traveling rail, configured to move in the first direction along two neighboring first rails among the first rails, and move in the second direction along two neighboring second rails among the second rails, the transfer robot comprising traveling wheels, guide wheels, and a wheel elevator,
wherein each of the first rails comprises a first traveling part and a first guide part protruding in a vertical direction from the first traveling part,
wherein each of the second rails comprises a second traveling part and a second guide part protruding in the vertical direction from the second traveling part,
wherein the wheel elevator is configured to move the traveling wheels in the vertical direction so that some of the traveling wheels are in contact with or spaced apart from the traveling rail,
wherein each of guide wheels has a rotating axis in the vertical direction, and
wherein the guide wheels are configured such that some of the guide wheels are in contact with at least one from among the first guide part and the second guide part while the transfer robot moves on the traveling rail.

2. The article transfer apparatus of claim 1, wherein
the traveling wheels comprise:
a first traveling wheel, at a first side of the transfer robot, and a third traveling wheel, at a third side of the transfer robot, each having a rotating axis in the second direction and spaced apart from each other in the second direction; and
a second traveling wheel, at a second side of the transfer robot, and a fourth traveling wheel, at a fourth side of the transfer robot, each having a rotating axis in the first direction and spaced apart from each other in the first direction, and
the guide wheels comprise:
at least one first guide wheel at the first side of the transfer robot and spaced apart from the first traveling wheel in the first direction;
at least one second guide wheel at the second side of the transfer robot and spaced apart from the second traveling wheel in the second direction;
at least one third guide wheel at the third side of the transfer robot and spaced apart from the third traveling wheel in the first direction; and
at least one fourth guide wheel at the fourth side of the transfer robot and spaced apart from the fourth traveling wheel in the second direction.

3. The article transfer apparatus of claim 2, wherein
the wheel elevator is configured to simultaneously vertically move the first traveling wheel and the third traveling wheel or the second traveling wheel and the fourth traveling wheel, and
the transfer robot is configured so that, in a case where the first traveling wheel and the third traveling wheel move in the vertical direction, the at least one first guide wheel and the at least one third guide wheel move together in the vertical direction.

4. The article transfer apparatus of claim 2, wherein
a separation distance in the second direction between an outer circumferential surface of the at least one first guide wheel and an outer circumferential surface of the at least one third guide wheel is less than a separation distance in the second direction between the first guide part of one of the two neighboring first rails and the first guide part of another of the two neighboring first rails, and
a separation distance in the first direction between an outer circumferential surface of the at least one second guide wheel and an outer circumferential surface of the at least one fourth guide wheel is less than a separation distance in the first direction between the second guide part of one of the two neighboring second rails and the second guide part of another of the two neighboring second rails.

5. The article transfer apparatus of claim 2, wherein a partial region of an outer circumferential surface of the at least one first guide wheel protrudes to an outer periphery of the transfer robot past an outer surface of the first traveling wheel.

6. The article transfer apparatus of claim 2, wherein
the at least one first guide wheel is a plurality of first guide wheels, the at least one second guide wheel is a plurality of second guide wheels, the at least one third guide wheel is a plurality of third guide wheels, and the at least one fourth guide wheel is a plurality of fourth guide wheels, and
the plurality of first guide wheels are spaced apart from each other with the first traveling wheel therebetween.

7. The article transfer apparatus of claim 2, further comprising a controller configured to:
in a case where the transfer robot moves in the first direction, cause a vertical level of a bottom surface of the at least one first guide wheel to be higher than a vertical level of a top surface of the first traveling part, and lower than a vertical level of a top surface of the first guide part; and
in a case where the transfer robot moves in the second direction, cause the vertical level of the bottom surface of the at least one first guide wheel and a vertical level of an outer circumferential surface of the first traveling wheel to be higher than the vertical level of the top surface of the first guide part.

8. The article transfer apparatus of claim 1, wherein each of the guide wheels has a horizontal width that decreases downward in the vertical direction.

9. The article transfer apparatus of claim 1, wherein an outer circumferential surface of each of the guide wheels comprises a rounded part that approaches a center of a bottom surface of the guide wheels in a downward direction.

10. The article transfer apparatus of claim 1, wherein an outer circumferential surface of each of the guide wheels is convex outward.

11. An article transfer apparatus comprising:
a traveling rail comprising:
first rails extending in a first direction and spaced apart from each other in a second direction perpendicular to the first direction; and
second rails extending in the second direction and spaced apart from each other in the first direction; and
a transfer robot on the traveling rail, configured to move in the first direction along two neighboring first rails among the first rails, and move in the second direction along two neighboring second rails among the second rails, the transfer robot comprising traveling wheels, guide wheels, and a wheel elevator,
wherein each of the first rails comprises a first traveling part and a first guide part protruding in a vertical direction from the first traveling part,
wherein each of second rails comprises a second traveling part and a second guide part protruding in the vertical direction from the second traveling part,
wherein a horizontal width of the first guide part and the second guide part narrows in the vertical direction,
wherein each of the guide wheels has a rotating axis in the vertical direction, and
wherein the guide wheels are configured such that some of the guide wheels are in contact with at least one from among the first guide part and the second guide part while the transfer robot moves on the traveling rail.

12. The article transfer apparatus of claim 11, wherein a horizontal width of an outer circumferential surface of each of the guide wheels decreases towards a bottom surface of the guide wheels.

13. The article transfer apparatus of claim 12, wherein
an angle formed by a side surface of the first guide part and a top surface of the first guide part of each of the first rails is the same as an angle formed by an outer circumferential surface of each of the traveling wheels and a bottom surface of each of the traveling wheels, and
an angle formed by a side surface of the second guide part and a top surface of the second guide part of each of the second rails is the same as the angle formed by the outer circumferential surface of each of the traveling wheels and the bottom surface of each of the traveling wheels.

14. The article transfer apparatus of claim 12, wherein
an angle formed by a side surface of the first guide part and a top surface of the first guide part of each of the first rails is greater than an angle formed by an outer circumferential surface of each of the traveling wheels and a bottom surface of each of the traveling wheels, and
an angle formed by a side surface of the second guide part and a top surface of the second guide part of each of the second rails is greater than the angle formed by the outer circumferential surface of each of the traveling wheels and the bottom surface of each of the traveling wheels.

15. The article transfer apparatus of claim 11, wherein
the traveling rail further comprises an intersection located at a point where one of the first rails and one of the second rails intersect, and
a vertical level of a top surface of the intersection is the same as a vertical level of a top surface of the first traveling part and a top surface of the second traveling part.

16. The article transfer apparatus of claim 15, wherein
the intersection further comprises protrusions protruding from the top surface of the intersection,
some of the protrusions of the intersection are in contact with the first guide part of the one of the first rails, and others of the protrusions of the intersection are in contact with the second guide part of the one of the second rails, and
a vertical level of a top surface of each of the protrusions is the same as a vertical level of a top surface of the first guide part.

17. The article transfer apparatus of claim 16, wherein
each of the protrusions comprises a first side surface and a second side surface facing in opposite directions from each other,
the first side surface is in contact with the first guide part or the second guide part, and
the second side surface comprises a rounded part such that the second side surface comes closer to the first side surface towards opposite side surfaces adjacent to the second side surface.

18. The article transfer apparatus of claim 11, wherein the traveling rail further comprises a identification tags, and the transfer robot further comprises a tag reader.

19. An article transfer apparatus comprising:
a traveling rail comprising:
first rails extending in a first direction and spaced apart from each other in a second direction perpendicular to the first direction; and
second rails extending in the second direction and spaced apart from each other in the first direction; and
a transfer robot on the traveling rail, configured to move in the first direction along two neighboring first rails among the first rails, and move in the second direction along two neighboring second rails among the second rails, the transfer robot comprising traveling wheels, guide wheels, and a wheel elevator,
wherein each of the first rails comprises a first traveling part and a first guide part protruding in a vertical direction from the first traveling part,
wherein each of the second rails comprises a second traveling part and a second guide part protruding in the vertical direction from the second traveling part,
wherein a horizontal width of the first guide part and the second guide part decreases in the vertical direction,
wherein each of the guide wheels has a rotating axis in the vertical direction,
wherein the guide wheels are configured such that some of the guide wheels are in contact with at least one from among the first guide part and the second guide part while the transfer robot moves on the traveling rail, and
wherein a horizontal width of each of the guide wheels decreases towards a bottom surface of the guide wheels.

20. The article transfer apparatus of claim 19, wherein
an angle formed by a side surface of the first guide part and a top surface of the first guide part of each of the first rails is greater than an angle formed by an outer circumferential surface of each of the traveling wheels and a bottom surface of each of the traveling wheels; and
an angle formed by a side surface of the second guide part and a top surface of the second guide part of each of the second rails is greater than the angle formed by the outer circumferential surface of each of the traveling wheels and the bottom surface of each of the traveling wheels.
